(19) United States
(12) Patent Application Publication
(10) Pub. No.: US 2018/0145200 A1
(43) Pub. Date: May 24, 2018

(54) MOUNTING ASSEMBLY

(71) Applicants: Shahriar Shamloo Aliabadi, Costa Mesa, CA (US); Michael Salvati, Santa Ana, CA (US)

(72) Inventors: Shahriar Shamloo Aliabadi, Costa Mesa, CA (US); Michael Salvati, Santa Ana, CA (US)

(21) Appl. No.: 15/360,801

(22) Filed: Nov. 23, 2016

(51) Int. Cl. H01L 31/05; H01L 31/048; H01L 31/02; H02S 40/36

(52) U.S. Cl. CPC H01L 31/0508; H01L 31/048; H02S 40/36; H01L 31/02021; H01L 31/0201; H01L 31/0504

(57) ABSTRACT

A mounting system is configured to contain and direct power from a photovoltaic cell. The mounting system includes a panel layer connected to at least one photovoltaic cell. A connection layer is joined to the panel layer and further includes a male connection, a female connection, and an electrical connection. The electrical connection is joined to the at least one photovoltaic cell. A support layer is joined to the connection layer forms a housing with the panel layer around the male connection, the female connection and the electrical connection. An electrical assembly is electrically coupled to the photovoltaic cell and the electrical connection and programmed with instructions to receive electrical power from the at least one photovoltaic cell. Then, convert the electrical power from direct current to alternating current. After that, transmit the alternating current to the electrical connection.

### BACKGROUND

The embodiments herein relate generally to systems that mount photovoltaic panels to a surface such as a roof

Prior to embodiments of the disclosed invention, photovoltaic solutions for flat roofs require mounting, ballast and anchoring, inner-row spacing and substantial wiring. Embodiments of the disclosed invention solve this problem with a system that provides improved wattage per square feet of photovoltaic installation and eliminates racking required on other systems.

### SUMMARY

A mounting system is configured to contain and direct power from a photovoltaic cell. The mounting system includes a panel layer connected to at least one photovoltaic cell. A connection layer is joined to the panel layer and further includes a male connection, a female connection, and an electrical connection. The electrical connection is joined to the at least one photovoltaic cell. A support layer is joined to the connection layer forms a housing with the panel layer around the male connection, the female connection and the electrical connection. An electrical assembly is electrically coupled to the photovoltaic cell and the electrical connection and programmed with instructions to receive electrical power from the at least one photovoltaic cell. Then, convert the electrical power from direct current to alternating current. After that, transmit the alternating current to the electrical connection.

### BRIEF DESCRIPTION OF THE FIGURES

The detailed description of some embodiments of the invention is made below with reference to the accompanying figures, wherein like numerals represent corresponding parts of the figures.

FIG. 1 shows a perspective view of one embodiment of the present invention shown in use;

FIG. 2 shows an exploded view of one embodiment of the present invention;

FIG. 3 shows an exploded view of one embodiment of the present invention;

FIG. 4 shows a top perspective view of one embodiment of the present invention;

FIG. 5 shows an exploded view of one embodiment of the present invention;

FIG. 6 shows a top perspective view of one embodiment of the present invention;

FIG. 7 shows an bottom perspective view of one embodiment of the present invention;

FIG. 8 shows a section assembly view of one embodiment of the present invention;

FIG. 9 shows a section view of one embodiment of the present invention;

FIG. 10 shows a top perspective view of one embodiment of the present invention;

FIG. 11 shows a top perspective view of one embodiment of the present invention;

FIG. 12 shows an exploded view of one embodiment of the present invention;

FIG. 13 shows an electrical schematic of one embodiment of the present invention; and

FIG. 14 shows a schematic of one embodiment of the present invention.

### DETAILED DESCRIPTION OF CERTAIN EMBODIMENTS

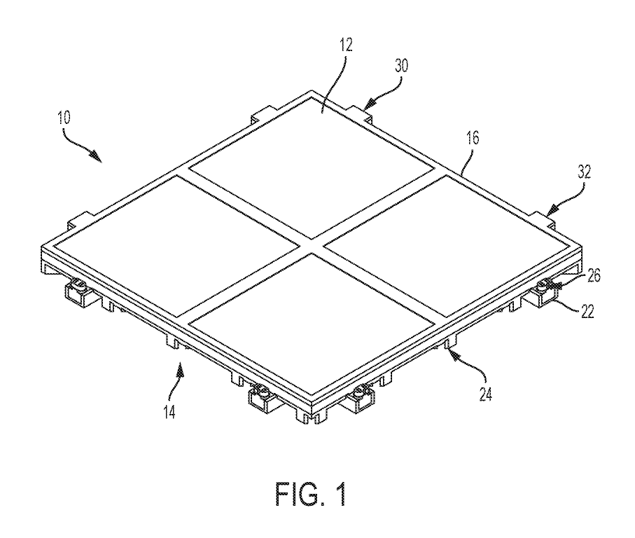

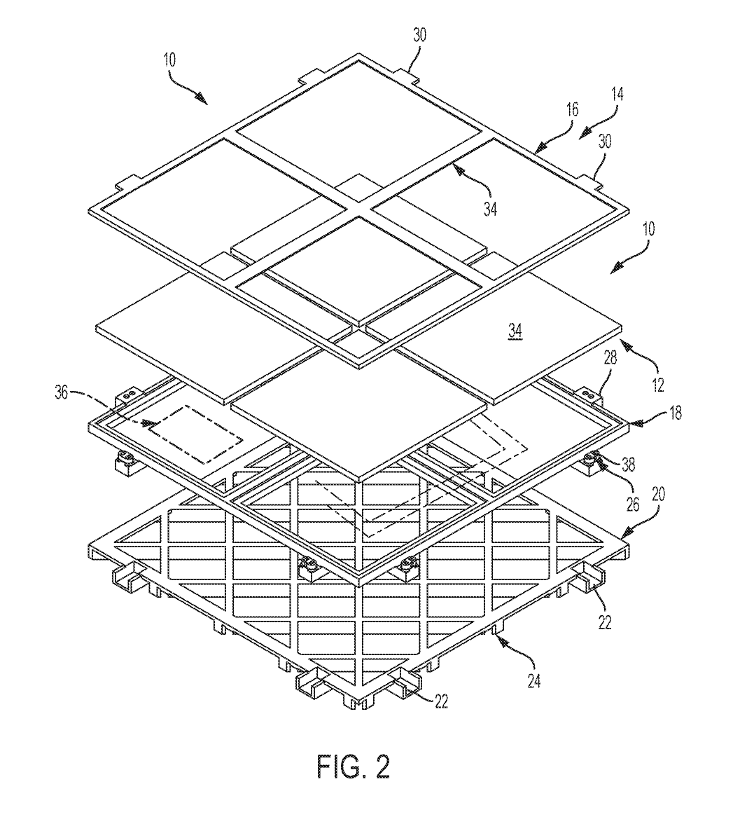

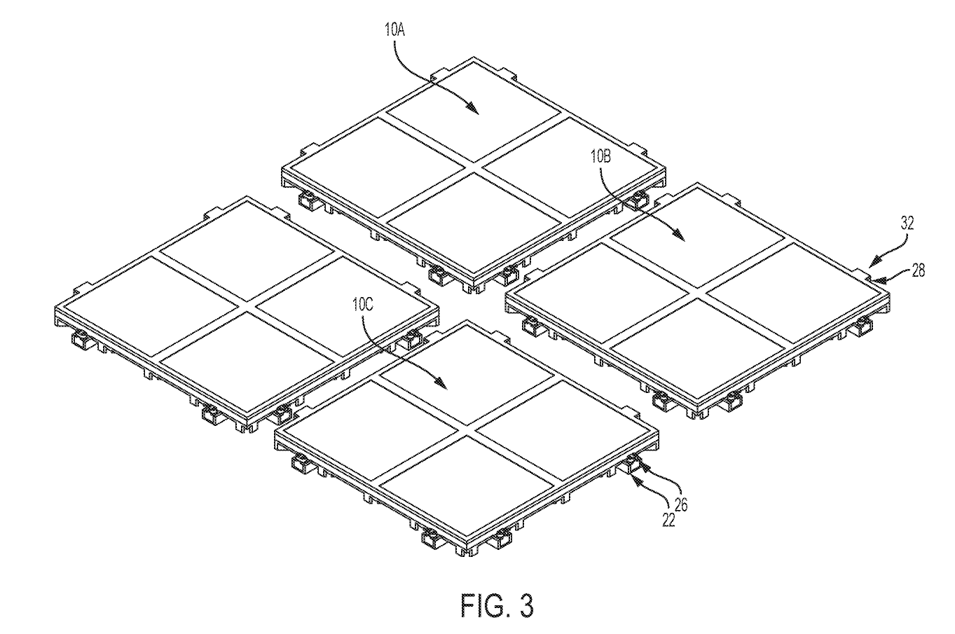

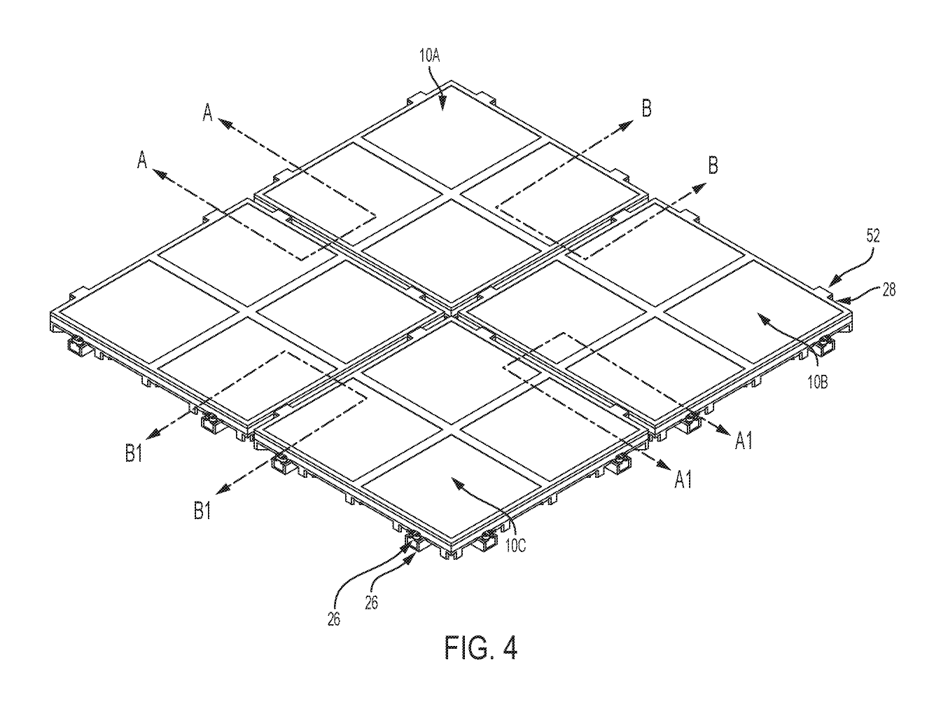

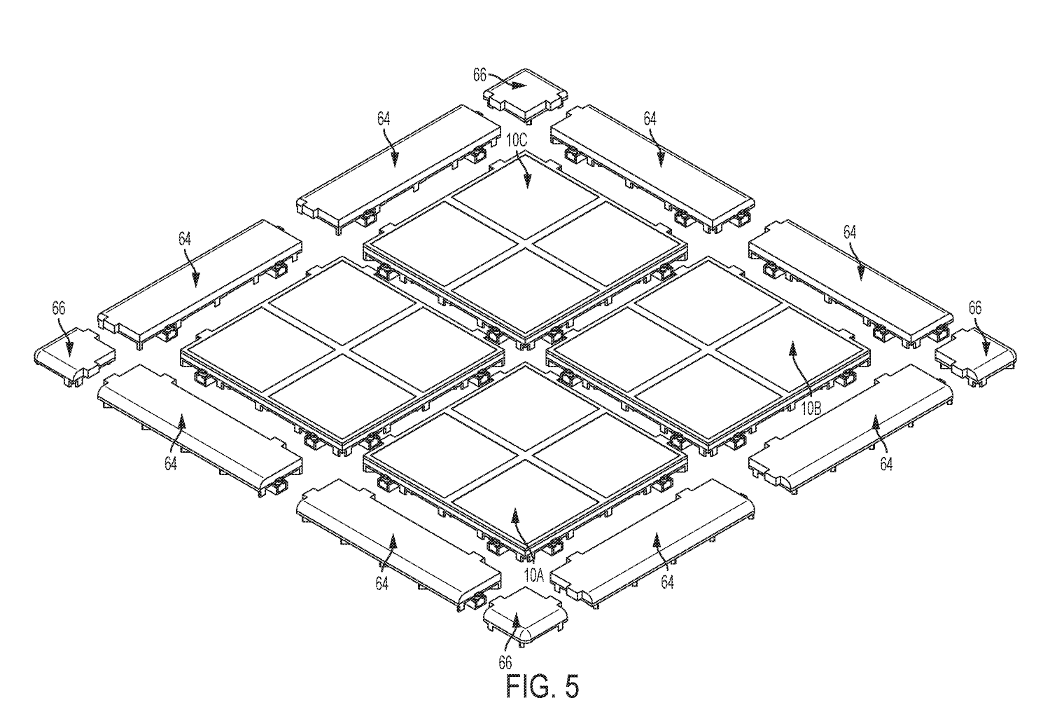

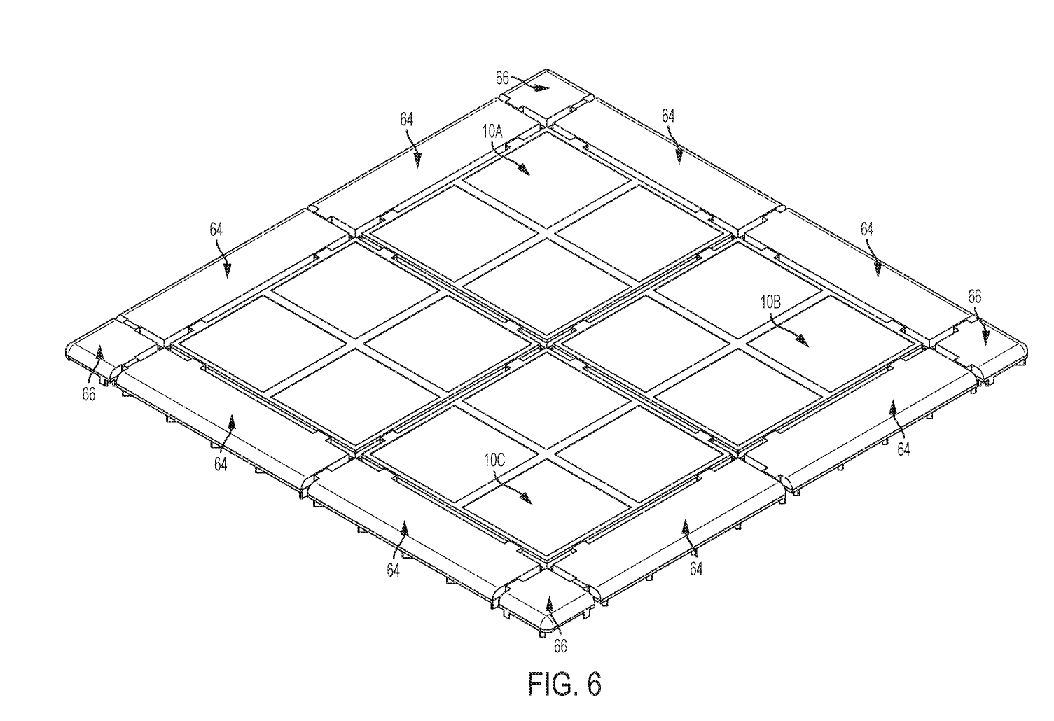

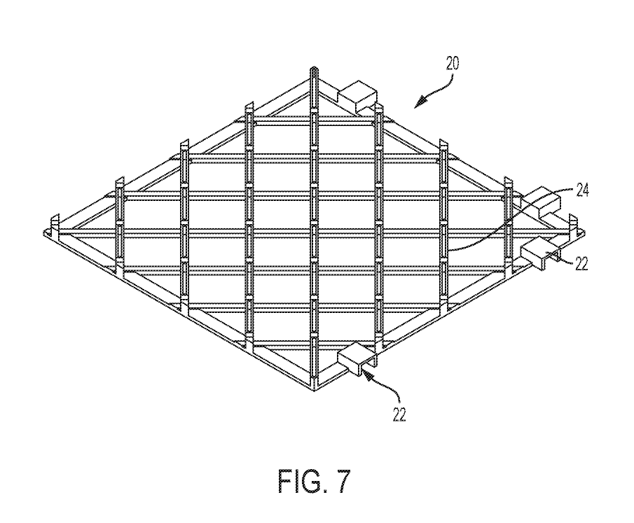

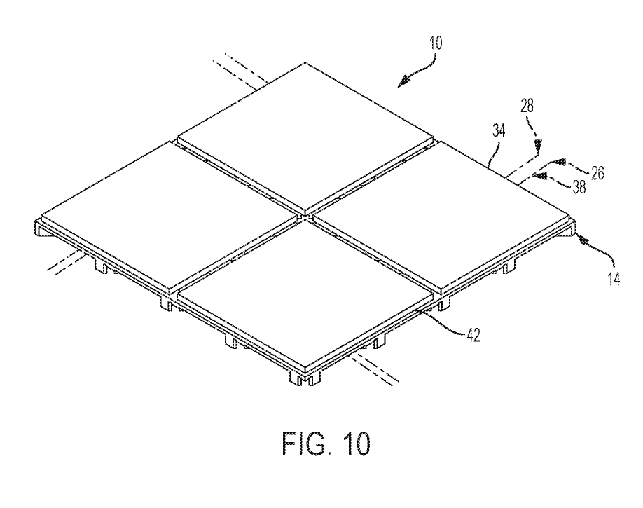

By way of example, and referring to FIGS. 1-14, one embodiment of the present system comprises a mounting system 10 for a photovoltaic cell assembly 12. The mounting system 10 further comprises an interlocking tile base structure 14.

The interlocking tile base structure 14 can be arranged as a quadrilateral, or a series of interlocked quadrilaterals. The interlocking base tile layer further comprises a panel layer 16, which is joined to a connection layer 18. A support layer 20 is also joined to the connection layer.

The support layer 20 further comprises at least two troughs 22 on each side. The support layer 20 further comprises system support structure 24 that provides support for the support layer 20 and the rest of the mounting system 10.

The connection layer 18 further comprises at least one male connector 26 and at least one female connector 28 on each side of the quadrilateral. Each male connector 26 is housed in a trough 22. Similarly, each female connector 26 is housed in a trough 22 when the connection layer 18 is joined to the support layer 20.

The panel layer 16 further comprises a plurality of trough covers 30. Each trough cover 30 covers a trough 22 forming a housing 32 there between. The panel layer 16 further comprises an internal support 34, connecting each side of the quadrilateral and further dividing the quadrilateral into four quadrilaterals. At least some of a photovoltaic cell assembly 12 fits into each quadrilateral.

The photovoltaic cell assembly 12 further comprises a photovoltaic cell 34 electrically coupled to an electrical assembly 36. The electrical assembly is electrically coupled to an integrated electrical connection 38 that is located in each housing 32. The integrated electrical connection 38, enables a first mounting system 10A to be electrically coupled to a second mounting system 10B, a third mounting system 10C and so on. In this way, the mounting system 10 can be scaled to a size and shape desired by an end user.

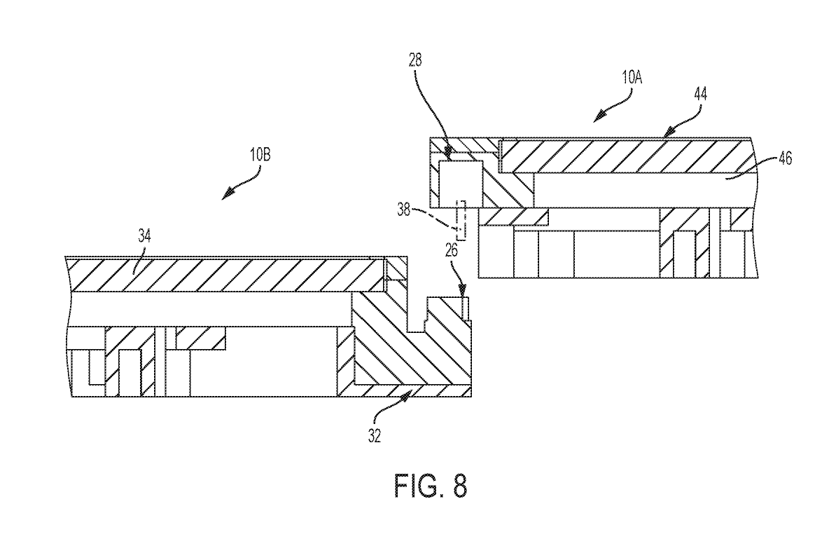

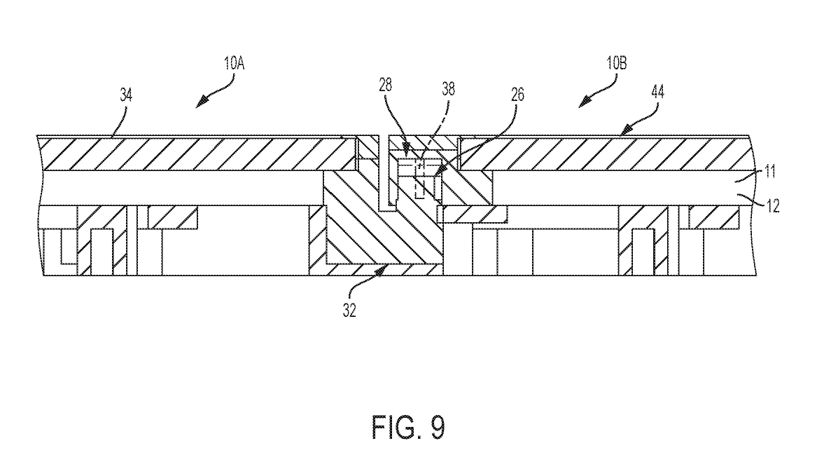

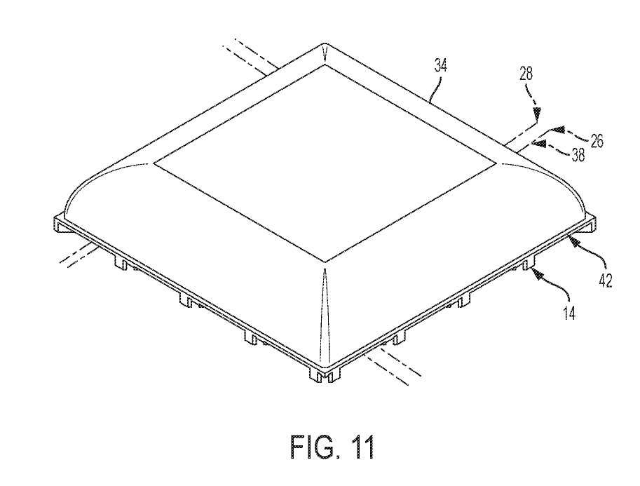

Photovoltaic cell 34 can be held in place using a variety of techniques. For instance, a cover 40 is shown over photovoltaic cell 34 is FIG. 8 and FIG. 9. In FIG. 11, a different shaped photovoltaic cell 34 is held in place with adhesive 42. This is non-limiting and other techniques can be used as well.

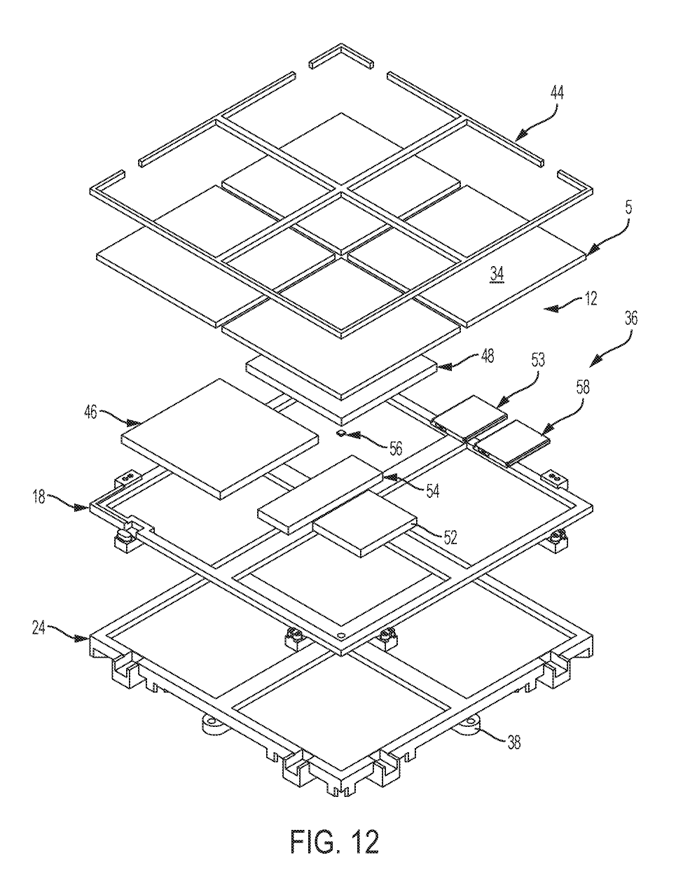

Turning to FIG. 12, a segmented protective surface 44 is used to hold photovoltaic cell 34. In some embodiments, the electrical assembly 36 can further comprise a power printed circuit board 46 electrically coupled to a micro-inverter board 48, rechargeable batteries 50, a communication module 52, an accessory module 54, and a light emitting diode indicator 56. Here, support layer 20 is mechanically coupled to anchor hole 58.

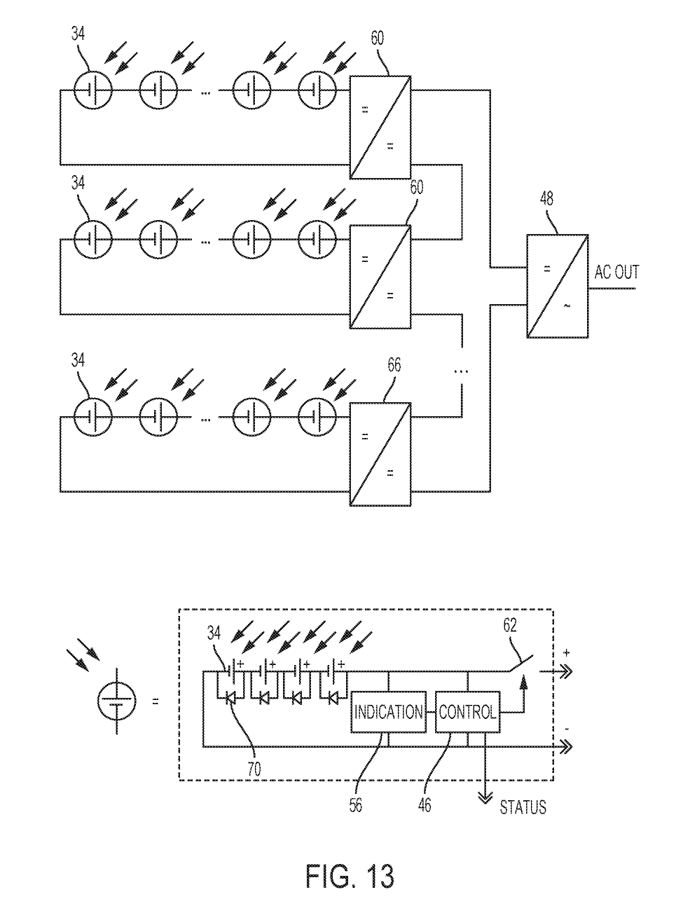

As shown in FIG. 13, a plurality of photovoltaic cells 34 is joined in series to a power optimizer 60. A plurality of power optimizers 60 is joined in parallel to micro-inverter board 48.

Functionally, each photovoltaic cell 34 is connected with a bypass diode and is joined with light emitting diode indicator 56 and power printed circuit board 46, which can operate a shutoff switch 62.

It is not always desirable to have electrical connectors on each photovoltaic cell 34 exposed to the elements. Embodiments of mounting system 10 solve that problem by connecting exposed outer edges of the mounting system 10 with side tile 64. A pair of side tiles 64 can be joined with a corner tile 66 that avoids exposed connections on the side tiles 64.

This arrangement provides a number of advantages. One of which is that an individual photovoltaic cell 34 can be turned off when malfunctioning or if there is simply no need for power at some particular time. This provides an individual user substantial control over functionality of a solar array. This control can be locally at the mounting system level, but, more likely, computer software can accomplish this in a number of ways.

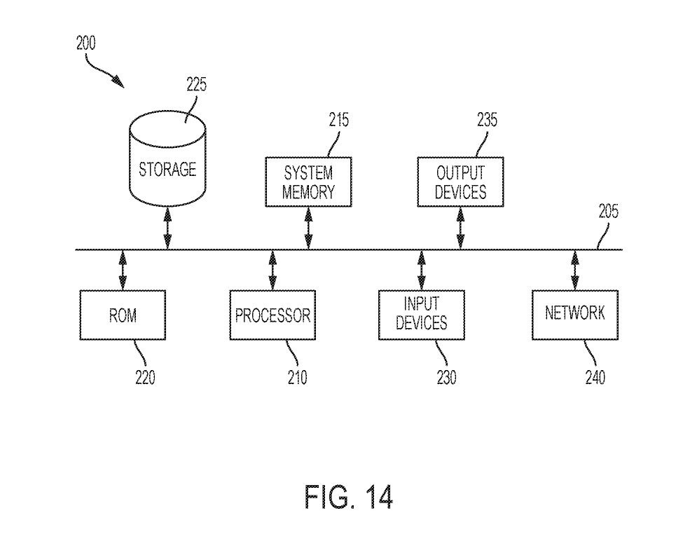

FIG. 14 conceptually illustrates an electronic system 200 with which some embodiments of the invention are implemented. The electronic system 200 may be a computer, phone, PDA, or any other sort of electronic device. Such an electronic system includes various types of computer readable media and interfaces for various other types of computer readable media. Electronic system 200 includes a bus 205, processing unit(s) 210, a system memory 215, a read-only 220, a permanent storage device 225, input devices 230, output devices 235, and a network 240.

The bus 205 collectively represents all system, peripheral, and chipset buses that communicatively connect the numerous internal devices of the electronic system 200. For instance, the bus 205 communicatively connects the processing unit(s) 210 with the read-only 220, the system memory 215, and the permanent storage device 225.

From these various memory units, the processing unit(s) 210 retrieves instructions to execute and data to process in order to execute the processes of the invention. The processing unit(s) may be a single processor or a multi-core processor in different embodiments.

The read-only-memory (ROM) 220 stores static data and instructions that are needed by the processing unit(s) 210 and other modules of the electronic system. The permanent storage device 225, on the other hand, is a read-and-write memory device. This device is a non-volatile memory unit that stores instructions and data even when the electronic system 200 is off. Some embodiments of the invention use a mass-storage device (such as a magnetic or optical disk and its corresponding disk drive) as the permanent storage device 225.

Other embodiments use a removable storage device (such as a floppy disk or a flash drive) as the permanent storage device 225. Like the permanent storage device 225, the system memory 215 is a read-and-write memory device. However, unlike storage device 225, the system memory 215 is a volatile read-and-write memory, such as a random access memory. The system memory 215 stores some of the instructions and data that the processor needs at runtime. In some embodiments, the invention's processes are stored in the system memory 215, the permanent storage device 225, and/or the read-only 220. For example, the various memory units include instructions for processing appearance alterations of displayable characters in accordance with some embodiments. From these various memory units, the processing unit(s) 210 retrieves instructions to execute and data to process in order to execute the processes of some embodiments.

The bus 205 also connects to the input and output devices 230 and 235. The input devices enable the person to communicate information and select commands to the electronic system. The input devices 230 include alphanumeric keyboards and pointing devices (also called “cursor control devices”). The output devices 235 display images generated by the electronic system 200. The output devices 235 include printers and display devices, such as cathode ray tubes (CRT) or liquid crystal displays (LCD). Some embodiments include devices such as a touchscreen that functions as both input and output devices.

Finally, as shown in FIG. 14, bus 205 also couples electronic system 200 to a network 240 through a network adapter (not shown). In this manner, the computer can be a part of a network of computers (such as a local area network (“LAN”), a wide area network (“WAN”), or an intranet), or a network of networks (such as the Internet). Any or all components of electronic system 200 may be used in conjunction with the invention.

These functions described above can be implemented in digital electronic circuitry, in computer software, firmware or hardware. The techniques can be implemented using one or more computer program products. Programmable processors and computers can be packaged or included in mobile devices. The processes may be performed by one or more programmable processors and by one or more set of programmable logic circuitry. General and special purpose computing and storage devices can be interconnected through communication networks.

Some embodiments include electronic components, such as microprocessors, storage and memory that store computer program instructions in a machine-readable or computer-readable medium (alternatively referred to as computer-readable storage media, machine-readable media, or machine-readable storage media). Some examples of such computer-readable media include RAM, ROM, read-only compact discs (CD-ROM), recordable compact discs (CD-R), rewritable compact discs (CD-RW), read-only digital versatile discs (e.g., DVD-ROM, dual-layer DVD-ROM), a variety of recordable/rewritable DVDs (e.g., DVD-RAM, DVD−RW, DVD+RW, etc.), flash memory (e.g., SD cards, mini-SD cards, micro-SD cards, etc.), magnetic and/or solid state hard drives, read-only and recordable Blu-Ray® discs, ultra-density optical discs, any other optical or magnetic media, and floppy disks. The computer-readable media may store a computer program that is executable by at least one processing unit and includes sets of instructions for performing various operations. Examples of computer programs or computer code include machine code, such as is produced by a compiler, and files including higher-level code that are executed by a computer, an electronic component, or a microprocessor using an interpreter.

As used in this application, the term “a” or “an” means “at least one” or “one or more.”

As used in this application, the term “about” or “approximately” refers to a range of values within plus or minus 10% of the specified number.

As used in this application, the term “substantially” means that the actual value is within about 10% of the actual desired value, particularly within about 5% of the actual desired value and especially within about 1% of the actual desired value of any variable, element or limit set forth herein.

All references throughout this application, for example patent documents including issued or granted patents or equivalents, patent application publications, and non-patent literature documents or other source material, are hereby incorporated by reference herein in their entireties, as though individually incorporated by reference, to the extent each reference is at least partially not inconsistent with the disclosure in the present application (for example, a reference that is partially inconsistent is incorporated by reference except for the partially inconsistent portion of the reference).

A portion of the disclosure of this patent document contains material which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

Any element in a claim that does not explicitly state “means for” performing a specified function, or “step for” performing a specified function, is not to be interpreted as a “means” or “step” clause as specified in 35 U.S.C. § 112, ¶ 6. In particular, any use of “step of” in the claims is not intended to invoke the provision of 35 U.S.C. § 112, ¶ 6.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

What is claimed is:

1. A mounting system, configured to contain and direct power from a photovoltaic cell, the mounting system comprising:
a panel layer, connected to at least one photovoltaic cell;
a connection layer, joined to the panel layer and further comprising: a male connection, a female connection, and an electrical connection; wherein the electrical connection is joined to the at least one photovoltaic cell;
a support layer, joined to the connection layer, and forming a housing with the panel layer around the male connection, the female connection and the electrical connection;
an electrical assembly, electrically coupled to the photovoltaic cell and the electrical connection and programmed with instructions to:
receive electrical power from the at least one photovoltaic cell;
convert the electrical power from direct current to alternating current; and
transmit the alternating current to the electrical connection.

2. The mounting system of claim 1, wherein the mounting system is a quadrilateral with at least one male connection, at least one female connection and at least one electrical connection on each side of the quadrilateral.

3. The mounting system of claim 2, wherein the electrical assembly further comprises: a power printed circuit board electrically coupled to a micro-inverter board, rechargeable batteries, a communication module, an accessory module, and a light emitting diode indicator.

4. The mounting system of claim 3, wherein the at least one photovoltaic cell is a plurality of photovoltaic cells joined in series to a power inverter.

5. The mounting system of claim 4, wherein the power optimizer is electrically coupled to the micro-inverter board.
